(19) United States
(12) Patent Application Publication
(10) Pub. No.: US 2026/0363109 A1
(43) Pub. Date: Nov. 12, 2026

(54) VIA STRUCTURES AND METHODS FOR MANUFACTURING THE SAME

(71) Applicant: Adeia Semiconductor Bonding Technologies Inc., San Jose, CA (US)

(72) Inventors: Cyprian Emeka Uzoh, San Jose, CA (US); Belgacem Haba, Saratoga, CA (US); Rajesh Katkar, Milpitas, CA (US)

(21) Appl. No.: 19/227,243

(22) Filed: Jun. 3, 2025

Related U.S. Application Data
(60) Provisional application No. 63/802,153, filed on May 8, 2025.

(51) Int. Cl. H10W 70/65; H10W 70/60; H10W 70/63; H10W 74/01; H10W 74/10; H10W 90/00

(52) U.S. Cl. CPC H10W 70/65; H10W 70/611; H10W 70/635; H10W 74/01; H10W 74/131; H10W 90/794

(57) ABSTRACT

In some implementations, a device package includes a semiconductor substrate having a first side, the first side comprising circuitry formed thereon, and a second side opposite the first side, wherein a section of the semiconductor substrate comprises a device. The device package further includes a first dielectric portion disposed over the section and the device, wherein the first dielectric portion comprises a first dielectric material, a second dielectric portion disposed adjacent to a sidewall of the section and over the circuitry on the first side, wherein the second dielectric portion comprises a second dielectric material different from the first dielectric material, a first conductive via disposed through the first dielectric portion and extending to the device, and a second conductive via disposed through the second dielectric portion and extending to the circuitry on the first side.

### CROSS REFERENCE TO RELATED APPLICATION

This application claims the benefit of U.S. Provisional Patent Application No. 63/802,153, filed May 8, 2025, which is hereby incorporated by reference herein in its entirety.

### TECHNICAL FIELD

The present disclosure relates to advanced packaging for microelectronic devices, and in particular, conductive via structures having reduced coupling losses.

### BACKGROUND

Three-dimensional integrated circuits (3D IC) technology faces challenges such as noise and parasitic coupling losses and reduction or miniaturization of device packaging. Some approaches for interconnecting devices (e.g., within a package, between packages, etc.) utilize through-substrate-vias or through-silicon-vias (TSVs). However, conventional TSVs cause tensile stress in the area around the TSV and impose physical constraints to maintain acceptable device performance, such as large keep-out zones around a TSV. Accordingly, there is a need for conductive structures designed to enable more compact device packaging and to reduce parasitic coupling losses, such as via-to-via coupling and/or via-to-device and/or substrate coupling.

### SUMMARY

Embodiments described in the present disclosure provide for a device package including one or more conductive structures for improving the performance of a device or package. The conductive structures may be designed for reducing parasitic coupling losses, such as via-to-via coupling and/or via-to-device and/or substrate coupling. In some embodiments, the device package includes a plurality of conductive vias disposed through one or more dielectric layers and/or at least a portion of a semiconductor substrate. In one embodiment, a first conductive via of the plurality of conductive vias extends through a first portion of a dielectric layer, contacting a side of a device (e.g., a backside of the device), and a second conductive via of the plurality of conductive vias extends through a second portion of the dielectric layer to connect to circuitry disposed at an opposite side of the dielectric layer or semiconductor substrate, such as circuitry that is part of a back-end-of-line (BEOL) layer.

Beneficially, conductive vias disposed through a dielectric layer and/or a substrate (referred to herein as through-dielectric vias (TDVs) and/or TSVs) are shielded from devices and/or from each other by the intervening dielectric material. That is, the intervening dielectric may have a thickness sufficient to reduce or minimize noise, signal coupling, and/or frequency-based losses compared to other conventional approaches. Beneficially, such conductive vias can provide reduced structural stress, smaller keep-out zones, reduced coupling losses (e.g., between vias and/or between vias and devices and/or substrates), reduced parasitic capacitance, faster switching speeds, lower production costs, increased bandwidth, lower RC delay, reduced memory latency (e.g., for high-bandwidth memory (HBM)), and/or improved scalability for assemblies, packages, interposers, stacks, etc.

Beneficially, using the conductive vias (e.g., TDVs and/or TSVs) as described in the present disclosure enables forming a directly bonded stacked structure including dies coupled to one or more other dies within the stacked structure and/or circuitry at an opposite side of the stacked structure through the conductive vias. That is, using the conductive vias (e.g., TDVs and/or TSVs) may enable improved miniaturization of device packages by reducing keep-out zones and improved device performance by reducing the parasitic coupling and/or other interference (e.g., circuit noise and losses at high frequencies).

One general aspect includes a device package. The device package includes a semiconductor substrate having a first side and a second side opposite the first side. The first side comprises circuitry formed thereon. A section of the semiconductor substrate includes a device. The device package further includes a first dielectric portion disposed over the section and the device. The device package further includes a second dielectric portion disposed adjacent to a sidewall of the section and over or across the circuitry on the first side. The device package further includes a first conductive via and a second conductive via. The first conductive via is disposed through the first dielectric portion and extends to the device. The second conductive via is disposed through the second dielectric portion and extends to the circuitry on the first side. In some embodiments, a first dielectric layer comprises the first dielectric portion, and a second dielectric layer comprises the second dielectric portion. The first dielectric portion may comprise a first dielectric material, and the second dielectric portion may comprise a second dielectric material different from the first dielectric material. In some embodiments, a dielectric layer comprises the first dielectric portion and the second dielectric portion, and the first and second dielectric portions comprise a same dielectric material. In some embodiments, the first and second conductive vias comprise a same conductive material. In some embodiments, the first conductive via may include a conductive material different from the second conductive via. In some embodiments, a width of the first conductive via may be smaller than a width of the second conductive via.

Implementations of the device package may include one or more of the following features. In some embodiments, the circuitry on the first side may be part of a back-end-of-line (BEOL) layer. For example, the BEOL layer may be formed over the first side of the semiconductor substrate, and the BEOL layer may comprise a bonding surface. The semiconductor substrate may be bonded to the BEOL layer, such as by direct dielectric bonds and/or direct hybrid bonds, formed between a bonding surface of the semiconductor substrate and a bonding surface of the BEOL layer. In some embodiments, the BEOL layer is formed by a damascene method over the first side of the semiconductor substrate. The second conductive via may extend to a first BEOL side of the BEOL layer and may be coupled to one or more conductive features extending from the first BEOL side to a second BEOL side of the BEOL layer opposite to the first BEOL side. In some embodiments, a third dielectric portion may be disposed over or adjacent to the second dielectric portion, and the second conductive via may extend through the third dielectric portion to the circuitry on the first side. The third dielectric layer may include the first dielectric material, the second dielectric material, or a dielectric material different from the first and second dielectric materials. In some embodiments, the first dielectric portion may be disposed vertically adjacent to the device, and the second dielectric portion may be disposed laterally adjacent to the device. In some embodiments, the device may be a first device, and the device package further includes a second device disposed over the semiconductor substrate. The second device may be coupled to one or more interconnects of the circuitry on the first side through the second conductive via. The second device may be coupled to the first device through the first conductive via. The circuitry on the first side may include one or more interconnects coupling the device and the second conductive via. The first conductive via may include a conductive material different from the second conductive via. A width of the first conductive via may be smaller than a width of the second conductive via.

One general aspect includes a method. The method includes providing a semiconductor substrate having a first side, wherein the first side comprises circuitry formed thereon, and wherein the semiconductor substrate includes a device. The method further includes forming a first dielectric layer over a second side of the semiconductor substrate, the second side opposite to the first side, wherein the first dielectric layer includes a first dielectric material. The method further includes forming a first conductive via extending through the first dielectric layer to the device, patterning the first dielectric layer and the semiconductor substrate to define a section including the device and a first dielectric portion disposed over the device, the first dielectric portion including the first dielectric material.

The method further includes forming a second dielectric portion adjacent to a sidewall of the section, wherein the second dielectric portion is disposed on or across the circuitry on the first side, and wherein the second dielectric portion includes a second dielectric material different than the first dielectric material, and forming a second conductive via extending through the second dielectric portion to the circuitry on the first side. In some embodiments, the circuitry on the first side may be part of a back-end-of-line (BEOL) layer.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1B (collectively referred to as FIG. 1) illustrate an example process of forming a directly bonded structure;

FIGS. 2A-2B shows some example structures including vias and backside connections, in accordance with embodiments of the present disclosure;

FIG. 3 shows an example structure including one or more devices at a first side of the example structure connected to circuitry disposed on an opposite, second side of the structure through via and/or backside connections, in accordance with embodiments of the present disclosure;

FIG. 4 shows an example structure including a redistribution layer (RDL) coupled to via and/or backside connections, in accordance with embodiments of the present disclosure;

FIG. 5 shows some intermediate structures illustrating an example process of forming via and/or backside connections disposed through a dielectric layer, in accordance with embodiments of the present disclosure;

FIG. 6 shows some intermediate structures illustrating an example process of forming via and/or backside connections disposed through first and second dielectric layers, in accordance with embodiments of the present disclosure;

FIG. 7 shows some example structures including via and/or backside connections in a die-to-wafer (D2W) structure, in accordance with embodiments of the present disclosure; and

FIG. 8 shows some example structures including via and/or backside connections in a wafer-to-wafer (W2W) structure and/or a die-to-wafer-to-wafer (D2W2W) structure, in accordance with embodiments of the present disclosure.

The figures herein depict various embodiments of the present disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the devices, packaging components, and assembly components described herein may be formed or mounted. The term “substrate” also includes semiconductor substrates that provide a supporting material upon which elements of a semiconductor device are fabricated or attached, and any material layers, features, and/or electronic devices formed thereon, therein, or therethrough. For ease of description elements, features, and devices formed therefrom are referred to in the singular or plural but should be understood to describe both singular and plural, e.g., one or more, unless otherwise noted. Examples of substrate material that may be used in these applications include, but are not limited to, Si, GaN, SiC, InP, GaP, InGaN, AlGaInP, AlGaAs, SiGe, Diamond, Diamond-Like-Carbon (DLC), etc., and/or combinations thereof.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that forms the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, devices, assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axes in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” and the like, either alone or in combination with a spatially relevant term, include both relationships with intervening elements and direct relationships where there are no intervening elements. Furthermore, the term “horizontal” and/or “lateral” are generally made with reference to the X-axis direction and the Y-axis direction set forth in the drawings. The term “vertical” is generally made with reference to the Z-axis direction set forth in the drawings.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

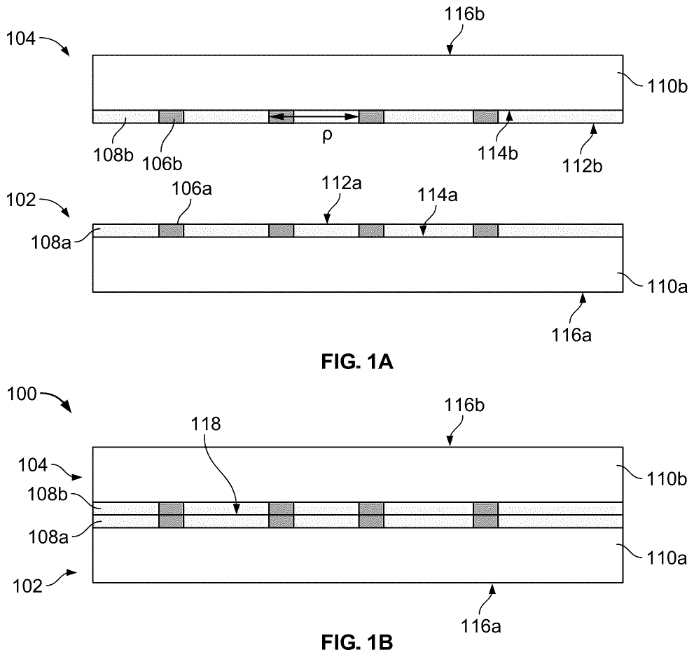

FIG. 1 illustrates an example process of forming a directly bonded structure. In some implementations (not illustrated), each bonding layer has one material. In these uniform direct bonding processes, only one material on each element is directly bonded.

Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through-substrate vias can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Patent Application Publication No. 20250006679, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line interconnect layers over such semiconductor portions. The bonding layers 108a, 108b can be provided as part of such BEOL layers during device fabrication, as part of one or more RDLs, or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), and active optical elements or devices, etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/°C or greater than 10 ppm/°C. For example, the CTE difference between the base substrate portions 110a and 110b can be in a range of 5 ppm/°C to 100 ppm/C, 5 ppm/°C to 40 ppm/°C, 10 ppm/°c to 100 ppm/°C, or 10 ppm/°C to 40 ppm/°C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, TSVs and/or other interconnect features (e.g., TDVs, optical interconnects) can be formed to provide vertical electrical communication or optical interconnection or both between and/or among the vertically-stacked elements. For example, the bonded structure 100 may include one or more optical interconnects that transmit data through optical signal communication between and/or among the vertically-stacked elements. The optical interconnect(s) may include one or more passive optical elements and/or one or more active optical elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer. In some embodiments, the first or second insulating layer may occlude one or more voids (not shown) within the dielectric layer or between the bonded structures.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). The activated surface may be rinsed with deionized water to remove any potential contaminates from the plasma chamber (for example particles) other suitable solvent or solvents. The cleaned activated substrate may be dried by spin drying or by other suitable methods. Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding).

Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm.

Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias). In some embodiments, any of the conductive features 106a and 106b and/or one or more thru-substrate features may comprise an optically conductive or nonconductive transparent material.

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element.

Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 200 μm, less than 100 μm, less than 50 μm, less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

It is noted that the present disclosure describes one or more first conductive features being interconnected with one or more second conductive features. It is appreciated that the one or more first conductive features may be interconnected with the one or more second conductive features through attaching one or more first elements (e.g., substrate, wafer, layer, etc.) and one or more second elements (e.g., substrate, wafer, layer, etc.) using one or more interconnect techniques. Some example interconnect techniques include direct bonding, anodic bonding, glass bonding, plasma-activated bonding, hybrid bonding, wire bonding, thermocompression, adhesive bonding, flip chip, conductive pins, conductive bumps, solder, reflow, interconnect technique variants, and/or combinations thereof. In some embodiments, respective surfaces of the one or more first elements and/or the one or more second elements may be modified (e.g., roughened, planarized) to enhance the bonds between the elements.

For example, a side of a first substrate may be roughened in preparation for direct bonding with a second substrate. For example, a side of a first substrate may be modified for flip chip bonding.

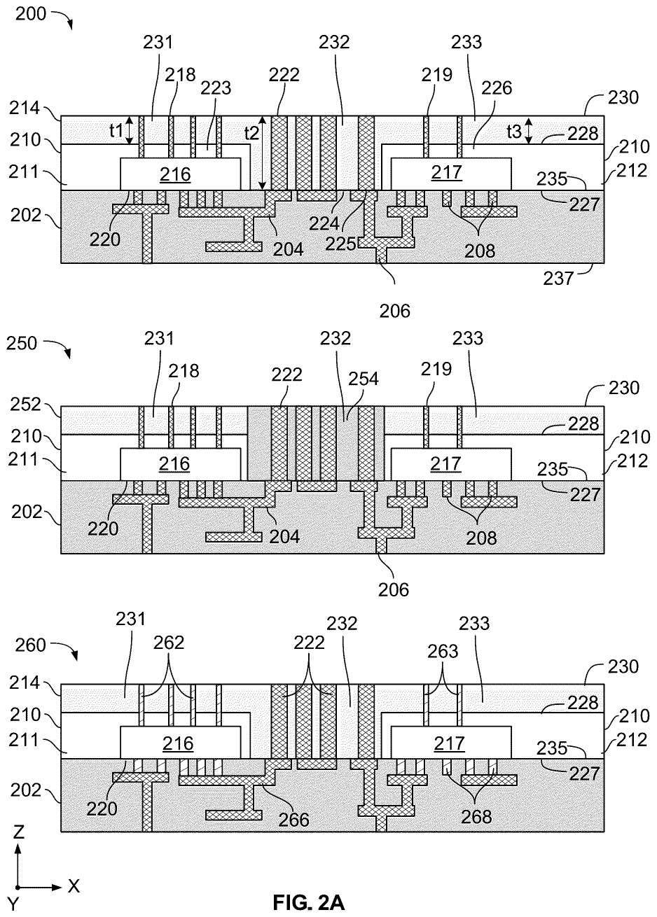

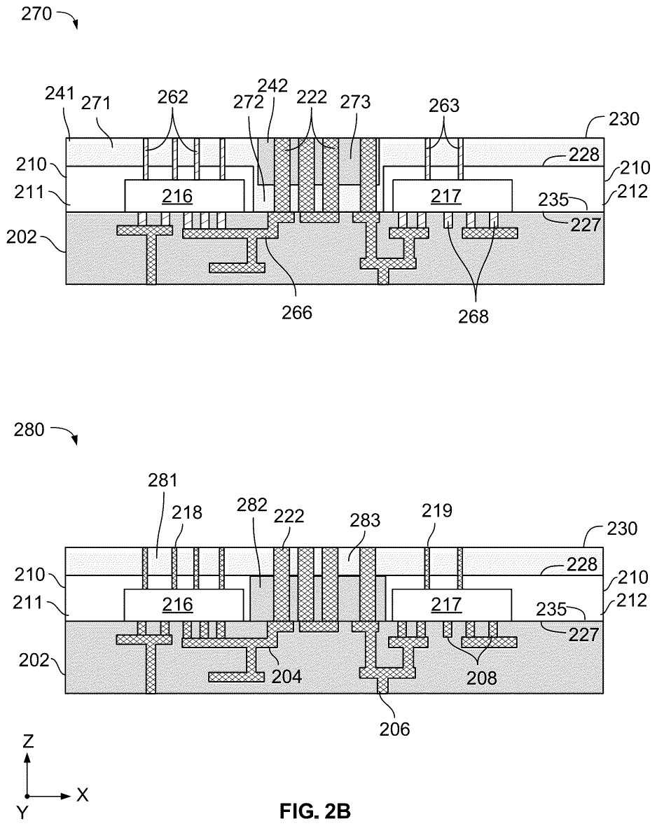

FIGS. 2A-2B show some example structures (e.g., structures 200, 250, 260, 270, 280) including vias and backside connections (e.g., simultaneous vias and backside connections), in accordance with embodiments of the present disclosure. Any of the structures may be part of a stack, a device package, an assembly, etc. Each of the structures may include a semiconductor substrate (e.g., semiconductor substrate 210), one or more dielectric layers (e.g., dielectric layers 214, first and second dielectric layers 252, 254, first and second dielectric layers 241, 242, etc.), and one or more conductive vias disposed through the one or more dielectric layers and/or a portion of the semiconductor substrate. The one or more dielectric layers may comprise an oxide, epoxy, polymer, glass, one or more low K dielectric materials, any suitable combination thereof, or any suitable dielectric material, such as those mentioned in the present disclosure, etc. Examples of dielectric materials may include epoxies, silicon oxides (e.g., fluorine-doped silicon oxide, fluorosilicate glass, fluorinated silica glass, carbon-doped silicon dioxide, porous silicon dioxide, porous carbon-doped silicon dioxide, etc.), organic polymeric dielectrics (e.g., spin-on organic polymers, polyimide, polynorbornene, benzocyclobutene, polytetrafluoroethylene (PTFE), etc.), silicon-based polymeric dielectrics (e.g., spin-on silicon-based polymers, hydrogen silsesquioxane (HSQ), methylsilsesquioxane (MSQ), etc.), other low K dielectrics, and/or combinations thereof. A first conductive via (e.g., conductive vias 218, 219, conductive vias 262, 263) may be disposed through the one or more dielectric layers and at least a portion of the semiconductor substrate to electrically connect to a semiconductor device (e.g., devices 216 or 217). A second conductive via (e.g., conductive vias 222) may be disposed through the one or more dielectric layers to electrically connect to circuitry disposed on an opposite side of the one or more dielectric layers or the semiconductor substrate. The vias may comprise any suitable conductive material. Examples of conductive materials may include silicon, polysilicon, silicide, Cu or other metals and/or metal alloys, tungsten, cobalt, TaN (e.g., hexagonal-TaN), Ta (e.g., alpha-Ta), TiN, a NiV alloy, ruthenium, and/or combinations thereof. In some embodiments, the first conductive via (e.g., conductive vias 218, 219, conductive vias 262, 263) may comprise any of silicon, polysilicon, silicide, tungsten, cobalt, TaN (e.g., hexagonal-TaN), Ta (e.g., alpha-Ta), TiN, a NiV alloy, ruthenium, and/or combinations thereof. In some embodiments, the second via (e.g., conductive vias 222) may comprise tungsten, copper (Cu), cobalt (Co), etc. Each structure may further comprise a BEOL layer (e.g., BEOL layer 202), and the circuitry may be disposed in the BEOL layer.

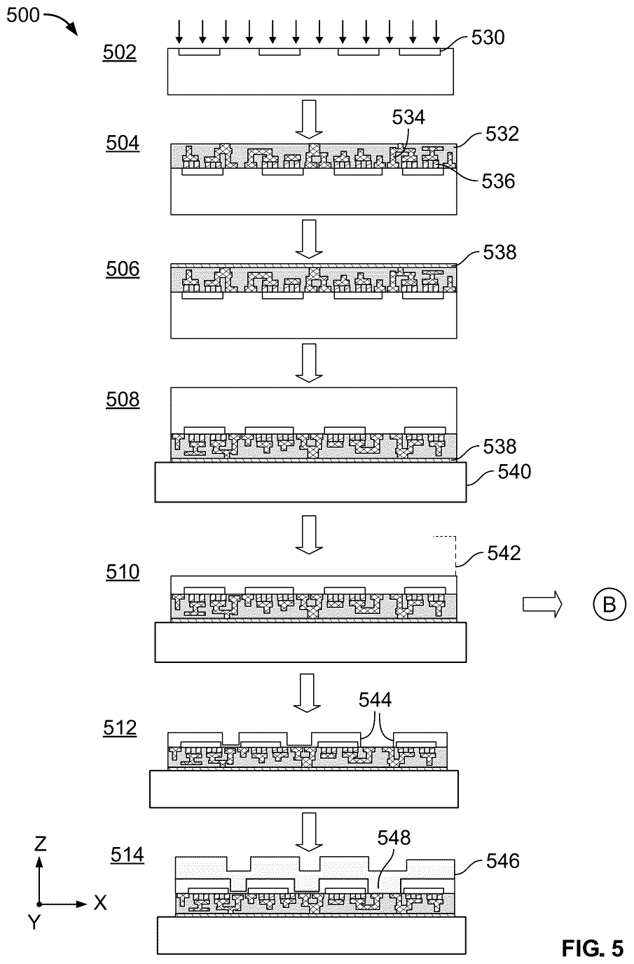

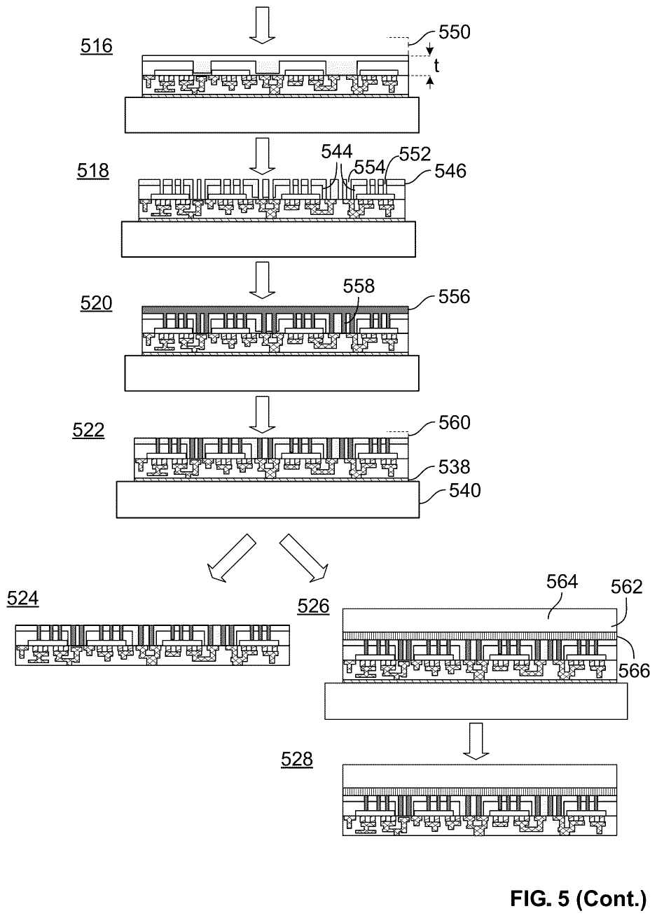

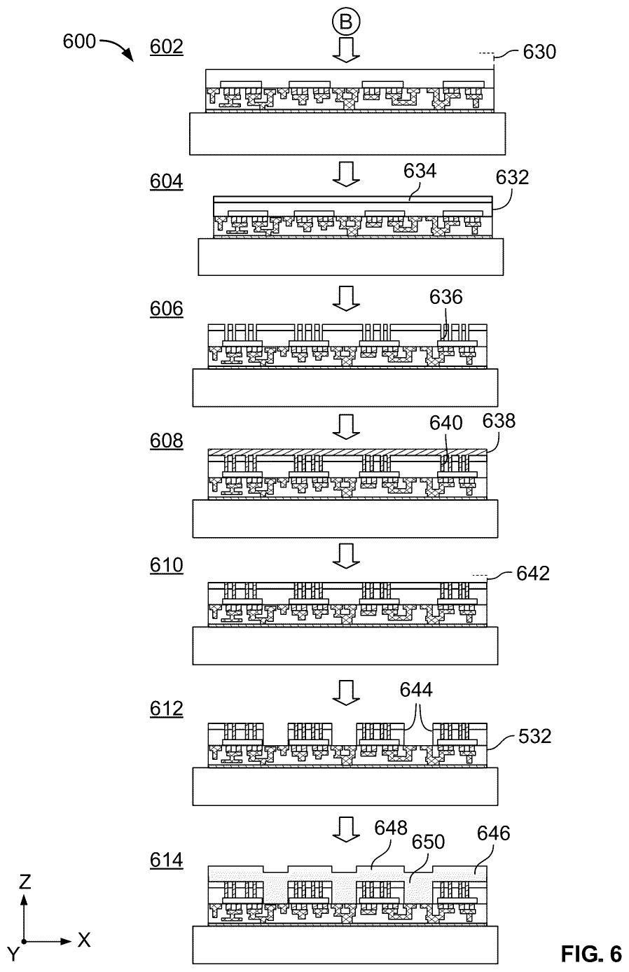

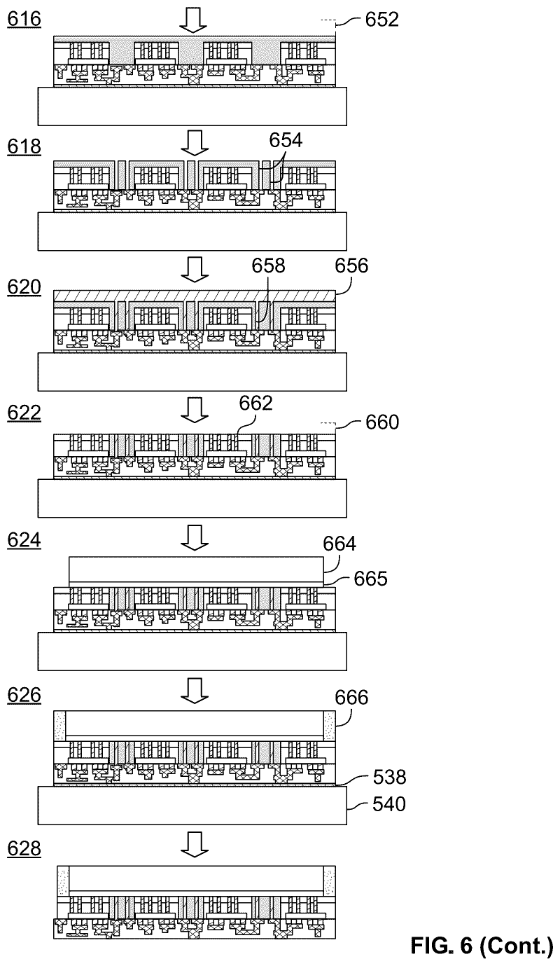

In some embodiments, the structure 200 of FIG. 2A may be formed by the process 500 shown in FIG. 5 (e.g., blocks 502 to 524). In some embodiments, the structure 260 may comprise different dielectric materials as shown in structure 250 (e.g., dielectric layer 214 is replaced with dielectric layers 231 and 232), and may be formed by the process 600 shown in FIG. 6 (e.g., blocks 602 to 622, further comprising removing the protective coating 538 and support layer 540).

Turning now to FIG. 2A, structure 200 includes a substrate 210 has a first side 227 (e.g., lower side, lower substrate side) and a second side 228 (e.g., upper side, upper substrate side) opposite the first side 227. A BEOL layer 202 is disposed on the first side 227 of the substrate 210. The BEOL layer 202 has a first side 235 (e.g., upper side, upper BEOL side) and a second side 237 (e.g., lower side, lower BEOL side) opposite the first side 235.

A dielectric layer 214 is disposed on the second side 228 of the substrate 210 and the first side 235 of the BEOL layer 202.

The substrate 210 includes sections 211 and 212. Each section includes a device (e.g., semiconductor device, integrated circuit, chip, etc.). For example, section 211 includes a device 216, and section 212 includes a device 217. Although a particular number of sections are shown in various embodiments of this disclosure (e.g., 2), there may be any suitable number of sections in a substrate (e.g., 1, 2, 3 or more, etc.). The substrate 210 may comprise any suitable semiconductor material (e.g., silicon). In some embodiments, the substrate may be a silicon-on-insulator (SOI) composition or include a lateral insulator or insulation layer.

The BEOL layer 202 includes conductive features 204, 206, 208. In some embodiments, the BEOL layer may comprise a plurality of levels or layers. For example, the BEOL layer may comprise two or more layers, 2-20 layers, more than two, five, ten, or twenty layers. The conductive features 204, 206, 208 may comprise any suitable conductive materials, such as those mentioned in the present disclosure, etc. The conductive features may include vias, segments, pads, etc. The conductive features 204 may couple (e.g., electrically connect, contact, directly or indirectly connect or contact, etc.) the device 216 to one or more conductive vias 222 disposed through the dielectric layer 214 and/or to a device (e.g., disposed on another side or lower side of the BEOL (not shown). The conductive features 206 may couple the device 217 to one or more conductive vias 222 disposed through the dielectric layer 214 and/or to a device at a lower BEOL side (not shown). The device 217 may be coupled to the conductive features 206 through one or more of the conductive features 208. In some embodiments, the conductive features 206 may include bumps, solder, or other interconnects. In some embodiments, the conductive features 204 and/or 208 may include bumps, solder, or other interconnects.

In some embodiments, the BEOL layer and/or circuitry are formed as a separate layer and attached to the semiconductor substrate. For example, the BEOL layer 202 may be formed over a first side of the substrate 210, and the BEOL layer 202 may comprise a bonding surface. In some embodiments, the BEOL layer 202 may be formed using a damascene method over a first side of the substrate 210. The circuitry and/or other conductive features of the BEOL layer may be coupled to the devices and/or conductive vias. The BEOL layer and/or circuitry may be formed as a separate layer and bonded (e.g., using direct bonding) to the semiconductor substrate, and the circuitry may be coupled to the devices and/or conductive vias through the bonds between the BEOL layer and the semiconductor substrate. For example, a wiring layer may be deposited on a side of the semiconductor substrate and/or attached (e.g., directly bonded, using an adhesive layer, using conductive bumps, etc.) to the devices and/or the conductive vias. In some embodiments, the BEOL layer may be hybrid bonded or flip chip attached to another stack of substrates.

In some embodiments, the BEOL layer 202 may be directly bonded to the substrate 210 (e.g., sections 211, 212), and/or the dielectric layer 214 (e.g., using dielectric-to-dielectric bonding, metal-to-metal bonding, hybrid bonding, etc.). For example, the substrate 210 may be bonded to the BEOL layer 202, such as by direct dielectric bonds and/or direct hybrid bonds, formed between a bonding surface of the substrate 210 and a bonding surface of the BEOL layer 202. Each of the sections 211 and 212 may have a respective side (e.g., lower substrate side, second side 227) with respective conductive features disposed thereon. For example, the device 217 may be coupled to the conductive features 208, and the device 216 may be coupled to a different set of conductive features 204 that are not coupled to the conductive features 208. In some embodiments, the devices 216, 217 may be coupled to the circuitry on the lower substrate side (e.g., side 227) through direct bonds (e.g., hybrid bonds) between the BEOL layer 202 and the substrate 210, such as at the BEOL-substrate bonding interface 220. In some embodiments, the devices 216, 217 may be coupled to the circuitry on the lower side (e.g., side 227) of the substrate 210 through conductive bumps, solder, and/or other interconnects.

The dielectric layer 214 has a first side 230 (e.g., upper side) and a second side opposite the first side (e.g., lower side). The dielectric layer 214 may comprise oxide, epoxy, polymer, glass, any combination thereof, or any suitable dielectric material, such as those mentioned in the present disclosure, etc. In some embodiments, the dielectric layer 214 may comprise a low-k dielectric material or a multi-dielectric layer. The dielectric layer 214 includes a dielectric portion 231 disposed over the section 211 and the device 216, a dielectric portion 232 disposed adjacent to sidewalls of section 211, 212, and a dielectric portion 233 disposed over the section 212 and the device 217. The dielectric portion 231 has a thickness t1, the dielectric portion 232 has a thickness t2, and the dielectric portion 232 has a thickness t3. In some embodiments, the thicknesses t1 and t3 of the dielectric portions 231 and 233 are substantially the same. The dielectric portion 232 may abut a side of the BEOL layer 202 (e.g., first side 235). Here, the dielectric portions 231, 232, 233 are from a same layer and comprise a same material (e.g., include substantially the same or the same dielectric material). In some embodiments, the dielectric portions may be from different dielectric layers and may comprise different dielectric materials (e.g., first dielectric layer 252 and second dielectric layer 254 in structure 260).

A conductive via 218 may be disposed through the dielectric portion 231 and through a portion 223 (e.g., upper substrate portion) of the section 211 and to the device 216. A conductive via 222 may be disposed through the dielectric portion 232 and to a side 235 (e.g., upper side) of the BEOL 202. A conductive via 219 may be disposed through the dielectric portion 233 and through a portion 226 (e.g., upper substrate portion) of the section 212 and to the device 217. The conductive via 218 is coupled to the device 216 (e.g., through interconnects at the device backside of the device), the conductive via 222 is coupled to the conductive features of the circuitry on the lower substrate side (e.g., conductive features 204, 206), and the conductive via 219 is coupled to the device 217. In some embodiments, the conductive via 222 may be coupled to the circuitry on the lower substrate side through direct bonds (e.g., hybrid bonds) between the BEOL layer 202 and the dielectric layer 214, such as at the BEOL-dielectric bonding interface 224 and/or metal-to-metal or conductive via to conductive material bonding interface 225. In some embodiments, the conductive via 222 may be coupled to the circuitry on the lower substrate side through conductive bumps, solder, and/or other interconnects. The first conductive via may extend through at least a portion of the semiconductor substrate being a semiconductor material (e.g., silicon).

In some embodiments, there may be no portion of the substrate 210 above the devices 216 and 217, and the conductive vias 218 and 219 may be through the dielectric layer 214 to the devices 216 and 217. In some embodiments, the substrate 210 may include a buried oxide layer, and the portion of the substrate above the devices 216 and 217 may comprise a dielectric material (e.g., oxide or silicon oxide).

The conductive vias 218, 219 may have substantially the same dimensions (e.g., lateral widths and/or vertical heights). In some embodiments, one or more of the conductive vias 218, 219, and/or 222 may have different heights and/or widths from another of the conductive vias 218, 219, and/or 222. In structure 250, the conductive vias 218 and 219, have a shorter height along the Z-direction than the conductive vias 222. The conductive vias 218 and 219 may have a narrower width along the X-and/or Y-directions than the conductive vias 222. The conductive vias 218, 219 and 222 comprise a same material. In some embodiments, the conductive vias may comprise different materials (e.g., as shown and described in relation to structure 260). The vias may comprise any suitable conductive materials, such as conductive materials mentioned in the present disclosure, etc.

The structure 250 includes dielectric portions with different materials. Structure 250 is similar to structure 200, except the dielectric portions 231 and 233 comprise different materials from the dielectric portion 232. The structure 250 includes a first dielectric layer 252 and second dielectric layer 254 in place of the dielectric layer 214 of structure 200. The first dielectric layer 252 is disposed vertically adjacent to the first section 211 and the second section 212. The second dielectric layer 254 is disposed laterally adjacent to the sections 211, 212 and between the devices 216, 217. The first dielectric layer 252 includes a different dielectric material from the second dielectric layer 254. For example, the first dielectric layer 252 may include an oxide, and the second dielectric layer 254 may include a low K dielectric material. In some embodiments, the first and second dielectric layer 252 and 254 may be applied to any suitable structure such as those mentioned throughout the present disclosure (e.g., used in place of the dielectric layers in structure 260, 300, etc.).

The structure 260 includes conductive vias with different conductive materials.

Structure 260 is similar to structure 200, except the vias 218 and 219 comprise different material from vias 222. The structure 260 includes conductive vias 262 and 263 in place of the conductive vias 218 and 219 of structure 200. The structure 260 further includes conductive features 266 and 268 in place of conductive features 204 and 208 of structure 200. One or more first conductive vias 262 includes a different conductive material from one or more second conductive vias 222. For example, the first conductive vias 262, 263 are used to contact devices 216, 217 and may comprise materials that are more compatible with the devices (e.g., reduce or minimize metal contamination). For example, the first conductive vias 262 and 263 may include a conductive material comprising silicon, polysilicon, silicide, tungsten, cobalt, hexagonal-TaN, alpha-Ta, TiN, NiV alloy, ruthenium, and combinations thereof. The second conductive vias 222 are disposed through dielectric 214 to contact circuitry in the BEOL layer 202 and may comprise materials for better performance. For example, the second conductive vias 222 may include a conductive material comprising tungsten, copper (Cu), cobalt (Co), etc. At least a portion of the conductive features 266 and the conductive vias 222 may include substantially the same conductive material. At least a portion of the conductive features 266 and the conductive vias 262 may include substantially the same conductive material. The conductive features 268 and the first conductive vias 262 may include substantially the same conductive material. In some embodiments, the conductive vias 262, 263, and 222 may be applied to any suitable structures such as those mentioned throughout the present disclosure (e.g., used in place of conductive vias in structure 200, 250, etc.).

In some embodiments, devices 216 and 217 may be referred to as first devices. In some embodiments, vias 218 and 219 may be referred to as first vias, and vias 222 may be referred to as second vias. The first vias may be referred to as TSVs, disposed in a dielectric layer and a portion of a substrate. The second vias may be referred to as TDVs, disposed in dielectric material. In some embodiments, portion 231 may be referred to as a first portion and portion 232 may be referred to as a second portion.

FIG. 2B shows conductive vias disposed through a plurality of dielectric layers.

The structure 270 is similar to the structure 200 except a first dielectric layer 241 and a second dielectric layer 242 replaces the dielectric layer 214 in structure 200. In FIG. 2B, a first dielectric layer 241 may comprise a first dielectric portion 271 disposed on the section 211 and a second dielectric portion 272 disposed adjacent to the section 211 and over or across the circuitry in the BEOL layer 202. A second dielectric layer 242 may comprise a third dielectric portion 273 disposed on the second dielectric portion 272. The second conductive via 222 may be disposed through the third dielectric portion 273 and the second dielectric portion 272, extending to the BEOL layer 202 and the conductive features 204, 206. The first and second dielectric portions 271 and 272 may comprise a different dielectric material than the third dielectric portion 273.

The structure 280 is similar to the structure 260 except a first dielectric layer and a second dielectric layer replaces the dielectric layer 214 in structure 200. A first conductive via 218 may be disposed through a first dielectric portion 281 disposed on the section 211. A second conductive via 222 may be disposed through the second dielectric portion 282 and the third dielectric portion 283, extending to the BEOL layer 202 and the conductive features 204, 206. A first dielectric layer may comprise the second dielectric portion 282 disposed adjacent to the section 211 and over or across the circuitry in the BEOL layer 202. A second dielectric layer may comprise the first dielectric portion 281 and the third dielectric portion 283. The first dielectric portion 281 may be disposed on the section 211, and the third dielectric portion 283 may be disposed on the second dielectric portion 282. The first and third dielectric portions 281 and 283 may comprise a same dielectric material. The second dielectric portion 282 may comprise a different dielectric material than the first and third dielectric portions 281 and 283.

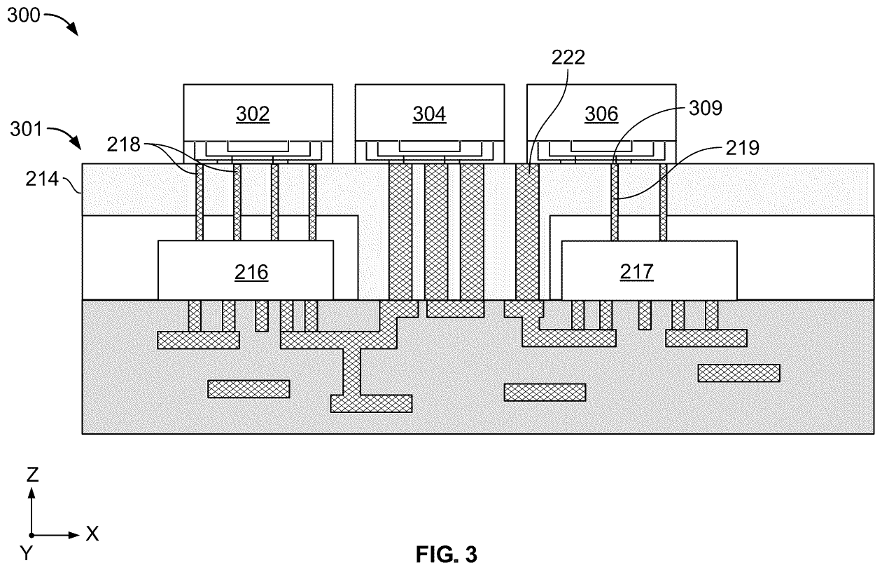

FIG. 3 shows an example structure 300 further including one or more devices (e.g., any devices 302, 304, and/or 306, upper devices) attached to the structure 301, in accordance with embodiments of the present disclosure. In some embodiments, the structure 301 corresponds to (e.g., is similar to or same as) structure 200 of FIG. 2A. Although FIG. 3 shows three devices 302, 304, and 306 attached to the structure 301, any suitable number of devices (e.g., one, two, three or more, etc.), and any suitable structure may be used (e.g., structure 250, 260, 270, 280, 401 etc.). In some embodiments, devices 216 and 217 may be referred to as first devices, and devices 302, 304, and 306 may be referred to as second devices. In some embodiments, vias 218 and 219 may be referred to as first vias, and vias 222 may be referred to as second vias. The first vias may be referred to as TSVs, disposed in a dielectric layer and a portion of a substrate. The second vias may be referred to as TDVs, disposed in dielectric material.

The devices 302, 304, and/or 306 are disposed on the structure 200. The devices 302, 304, and/or 306 may be separated from each other by one or more spaces therebetween. A BEOL or RDL may be disposed on the backside or device side of the devices 302, 304, and 306. The conductive vias 218 may electrically couple device 302 to device 216. The conductive via(s) 222 may electrically couple the device 304 and device 306 to one or more conductive features of the BEOL layer in structure 301. The conductive vias 219 may electrically couple the device 306 to the device 217. Device 304 and device 306 may be coupled to different conductive features of the BEOL layer in structure 301. Device 306 may be coupled to one or more conductive features of the BEOL layer in structure 301 and the device 217.

Any of the devices 302, 304, 306 may have a device side and a backside. The devices 302, 304, 306 may include logic and/or memory components. For example, the devices 302, 304, 306 may include logic components at the device side and a memory stack (e.g., HBM) at the backside. In some embodiments, a backside of one or more of the devices 302, 304, 306 is disposed on the dielectric layer 214. In some embodiments, a device side of one or more of the devices 302, 304, 306 is disposed on the dielectric layer 214. Each of the devices 302, 304, 306 is coupled to its respective vias 218, 222, or 219 through interconnects at its respective device side.

In some embodiments, a lower device 216 may be electrically or communicatively coupled to both upper devices 302 and 304 through an electrical or communication path formed through conductive features of the BEOL layer 202 and vias 222. The device 217 may be electrically coupled to the device 306 through a first electrical or communication path through conductive vias 219 and a second electrical or communication path through conductive vias 222. In structure 300, a side (e.g., upper side) of device 217 may be a backside, and an opposite side (e.g., lower side) of device 217 may be a device side. In some embodiments, a device side of device 217 may be coupled to a backside of device 217 through a first and/or a second electrical or communication path (e.g., conductive vias 219 and/or conductive vias 222).

In some embodiments, one or more of the devices 302, 304, and 306 may be coupled to their respective vias through direct bonds (e.g., hybrid bonds) formed between their respective device sides and respective portions of the dielectric layer 214. For example, the device side of the device 304 may be hybrid bonded to the dielectric layer 214 (e.g., through direct dielectric-to-dielectric bonds) and the conductive vias 222 (e.g., through direct metal-to-metal bonds). In some embodiments, one or more of the devices 302, 304, and 306 may be coupled to their respective vias through bumps, solder, and/or other interconnects disposed between the one or more upper devices and the dielectric layer 214. For example, the device 302 may be coupled to the conductive vias 218 using microbumps (not shown).

For example, the device 306 may be coupled to the conductive vias 219 using solder (not shown), such as disposed at an interface 309 between the device side of the device 306 and the conductive vias 219.

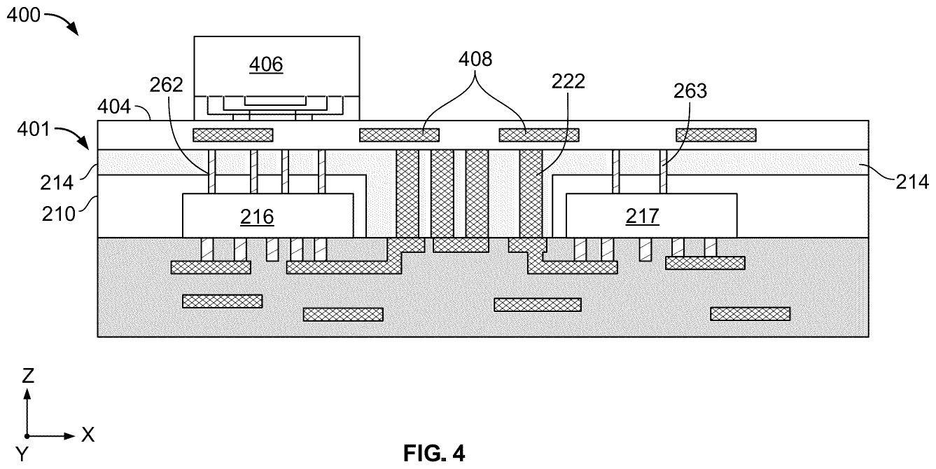

FIG. 4 shows an example structure 400 including an RDL 404 coupled to via and/or backside connections, in accordance with embodiments of the present disclosure. The RDL 404 is disposed over the structure 401, and a device 406 (with a BEOL layer or RDL disposed on the backside or frontside of the device 406) may be disposed on the RDL 404. In some embodiments, the structure 401 corresponds to (e.g., is similar to or same as) structure 260 of FIG. 2A. In some embodiments, the RDL 404 may be formed on the structure 401. In some embodiments, a BEOL layer or RDL may be formed or disposed on the backside or device side of the device 406. The device 406 may be bonded to the structure 401 at the respective BEOL layer or RDL bonding surfaces. Although FIG. 4 shows one device attached to the structure 260 of FIG. 2, any suitable number of devices (e.g., 2, 3 or more, etc.) may be attached to any suitable structures such as those mentioned in the present disclosure (e.g., structure 200, 250, 270, etc.). For example, devices 302, 304, and 306 of FIG. 3 may be disposed on the RDL 404 on the structure 260. The RDL 404 may be used with any structure mentioned in embodiments of the disclosure (e.g., structure 200, 250, 270, 280, etc.). The RDL 404 may include one or more interconnect features 408 (e.g., segments, pads, wiring, etc.) and may be used to electrically couple one or more first devices (e.g., devices 216, 217) to second devices (e.g., device 406 or devices 302, 304, and 306 of FIG. 3, etc.) through the interconnect features 408. The device 406 (e.g., RDL or BEOL layer disposed on the device 406) may be bonded (e.g., directly bonded, hybrid bonded) to the RDL 404. Additionally or alternatively, the one or more conductive vias 262, 263, 222 in the dielectric layer 214 may be coupled to the interconnect features 408 through solder, bumps, and/or other interconnects disposed between the RDL 404 and the dielectric layer 214.

In some embodiments, the conductive vias 222, 262, and/or 263 or vertical conductive layers may be plated separately from a horizontal or lateral conductive layers.

For example, horizontal connections in RDL may be formed separately from vertical vias. In some embodiments, instead of a separate RDL, the conductive vias 222, 262, and/or 263 or vertical conductive layers may be plated in a same step with horizontal or lateral conductive layers (e.g., formed in a same step using a dual damascene process). In some embodiments, conductive vias and conductive interconnects (e.g., conductive features, pads) may be formed using a dual damascene process. One or more conductive vias may contact a single pad. In some embodiments, the substrate 210 may include a buried power rail, and a conductive via may be formed on the buried power rail. The buried power rail may comprise cobalt. The buried power rail may be formed before a backside metallization is performed. A via may be formed to land on a buried power rail. In some embodiments, the substrate 210 may include conductive vias that were already formed before a backside metallization is performed. In some embodiments, a substrate be an SOI substrate. The SOI substrate may include a lateral insulator and have SOI on backside or a buried oxide for noise. In some embodiments, vias may go through an SOI layer, silicon, or can stop on buried oxide.

FIG. 5 shows some intermediate structures illustrating an example method or process 500 of forming via and/or backside connections disposed through a dielectric layer, in accordance with embodiments of the present disclosure. The method or process shown in FIG. 5 may be applied or used to form structures described in the present disclosure. For example, the structure formed at block 524 of FIG. 5 corresponds to (e.g., is similar to, same as) the structure 200 of FIG. 2A, etc.

The process 500 includes providing a semiconductor substrate having a first side, wherein the first side comprises circuitry formed thereon, and wherein the semiconductor substrate includes a device. At block 502, the process 500 includes providing a substrate having or including one or more devices 530 formed thereon. At block 504, the process 500 includes forming a BEOL layer 532. The process 500 includes forming circuitry as part of the BEOL layer 532 including conductive features 534 and/or 536. A first side of the BEOL layer 532 is disposed on the substrate. The first side of the BEOL layer 532 is adjacent to the devices 530.

In some embodiments, the process 500 includes forming a protective layer or protective coating. The protective layer may comprise silicon nitride or an organic material.

The protective layer may comprise multiple layers. The protective layer may be used to protect the BEOL layer 532 if attached to a supporting layer with adhesive. The protective layer may enable removal of adhesive residue after a BEOL layer is separated from the supporting layer. At block 506, the process 500 includes forming a protective coating 538 (e.g., a thin protective coating, protective layer) on a second side of the BEOL layer 532 that is opposite to the first side (e.g., a side facing away from the substrate and the devices 530). At block 508, the substrate, the BEOL layer 532, and the protective coating 538 are disposed on a support layer 540. The process 500 may include flipping and attaching the substrate with the BEOL layer 532 and protective coating 538 to the support layer 540. The protective coating 538 may be in contact with the support layer 540, and a side of the substrate opposite to the devices 530 may be exposed. In some embodiments, the substrate with the BEOL layer 532 may be attached using any suitable technique to another substrate (e.g., without protective coating 538 to another substrate or structure). For example, a reconstituted substrate or any suitable substrate such as those mentioned in the present disclosure may be used in place of a support layer 540.

At block 510, the process 500 includes thinning the substrate from the exposed side (e.g., a backside of the substrate) to remove a portion 542 of the substrate. In some embodiments, the thickness may be 20 μm or less, 16 μm or less, 5 μm or less, or 0.5 μm or less. In some embodiments, the substrate is thinned such that the remaining substrate and the devices 530 have substantially the same thickness along the Z-direction. That is, a side of the devices 530 may be exposed by removing the portion 542. In some embodiments, a first dielectric layer is formed on the thinned substrate, continuing to process 600, and is described further regarding FIG. 6.

The process 500 further includes patterning the semiconductor substrate to define a section including the device, wherein a sidewall of the section extends from a second side of the substrate, the second side opposite to the first side, to the circuitry on the first side.

Continuing the process 500, at block 512, the process 500 includes removing one or more portions from the substrate. In some embodiments, a portion of the substrate on the BEOL layer 532 may be partially removed or fully removed. The substrate may be patterned and selectively etched to define sections 544 having sidewalls separated by one or more spaces.

The portion of the substrate on the BEOL layer 532 may be substantially removed, leaving an exposed portion of the BEOL layer 532 (e.g., to provide the substrate 210 of embodiments of the present disclosure). The substrate may be patterned and selectively etched to define sections 544 having at least a portion of the sidewalls separated by one or more spaces, and a thin portion of the substrate may remain on a portion of the BEOL layer 532 disposed between the sections 544.

The process 500 further includes forming a dielectric layer over the second side of the semiconductor substrate. The dielectric layer includes a first dielectric portion disposed over the device and a second dielectric portion adjacent to the sidewall of the section. The second dielectric portion is disposed on the circuitry on the first side. At block 514, the process 500 includes forming a dielectric layer 546 on the substrate. One or more portions 548 of the dielectric layer 546 fill the spaces between the sections 544. At block 516, the dielectric layer 546 is planarized and/or thinned, and the process 500 includes removing a portion 550 of the dielectric layer 546 to define a planar dielectric surface over the substrate. The dielectric layer 546 may be thinned to have a thickness of 5 μm or substantially 5 μm. In some embodiments, the thickness may be less than 20 μm, 10 μm, 16 μm, 5 μm, or 0.5 μm, such as 0.2 μm or substantially 0.2 μm. The dielectric layer 546 includes one or more upper portions disposed on the sections 544. A thickness of the one or more upper portions disposed on the sections 544 may be 0.1 μm to 2 μm. In some embodiments, a thickness of the one or more upper portions disposed on sections 554 may be 2 μm or less, 1 μm or less, 0.7 μm or less, 0.5 μm or less, 0.3 μm or less, or 0.2 μm or less, such as 0.1 μm or substantially 0.1 μm. In some embodiments, the process may include forming a plurality of dielectric layers instead of a single dielectric layer and/or thinning one or more of the plurality of dielectric layers. In some embodiments, the process may include forming a plurality of dielectric layers to form a structure with multiple dielectric layers, such as shown and described in relation to FIG. 6 (e.g., forming a structure similar to structure 250 of FIG. 2A with a first dielectric layer 252 and a second dielectric layer 254). In some embodiments, a process may form a first dielectric layer 241, and a second dielectric layer 242 in place of the single dielectric layer 546 at block 514 to form a structure with multiple dielectric layers (e.g., structure 270 as shown in FIG. 2B). In some embodiments, a process may form a first dielectric layer (e.g., dielectric portion 282), and a second dielectric layer (e.g., dielectric portion 281) in place of the single dielectric layer 546 at block 514 to form a structure with multiple dielectric layers (e.g., structure 280 as shown in FIG. 2B).

The process 500 further includes patterning the dielectric layer to define a first opening extending through the first dielectric portion to the device and to define a second opening extending through the second dielectric portion to the circuitry on the first side. At block 518, the process 500 includes patterning the dielectric layer 546 to define one or more first openings 552 extending through the one or more upper portions of the dielectric layer 546 and one or more second openings 554 extending through the one or more portions 548 of the dielectric layer 546 between the sections 544. The sections 544 may be patterned such that the first openings 552 extend through substrate portions disposed on respective devices 530 of the sections 544. In some embodiments where substrate portions remain on portions of the BEOL layer 532 between the sections 544, the remaining substrate portions may be patterned such that the second openings 554 extend through the remaining substrate portions to the BEOL layer 532. In some embodiments, the process 500 includes forming a liner on sidewalls of the first dielectric portion defining the first opening and sidewalls of the second dielectric portion defining the second opening.

The process 500 further includes forming a first conductive via filling the first opening and extending through the first dielectric portion to the device and a second conductive via filling the second opening and extending through the second dielectric portion to the circuitry on the first side. At block 520, the process 500 includes forming a conductive layer 556. In some embodiments, the process 500 includes forming an adhesion and/or barrier layer prior to forming the conductive layer 556. In some embodiments, forming the conductive layer 556 includes forming a seed layer. Here, the conductive layer 556 includes one or more portions 558 that fill the first openings 552 and the second openings 554. At block 522, the process 500 includes thinning and planarizing the conductive layer 556 to remove a conductive layer portion 560. That is, the conductive layer portion 560 may be removed through polishing, such as by using CMP. Here, the conductive layer 556 is thinned to have substantially the same thickness as the dielectric layer 546 and form conductive vias filling the first openings 552 and the second openings 554. That is, the conductive vias may have a height along the Z-direction that is substantially the same as a thickness of the dielectric layer 546 along the same direction. In some embodiments, the process 500 includes removing the support layer 540 and/or the protective layer 538, continuing to block 524. The process 500 may include removing the support layer 540 and selectively removing the protective layer 538. At block 524, a structure is formed for assembly, such as stacking. In some embodiments, the structure formed at block 524 corresponds to (e.g., is same as or similar to) the structure 200 of FIG. 2A. In some embodiments, the process 500 includes assembling a stacked structure, continuing to block 526.

Although FIG. 5 shows a first conductive via to a device 530 formed at a same time as a second conductive via to a BEOL layer 532 is formed, in some embodiments, a first conductive via may be formed before or after a second via is formed. For example, in FIG. 6, a first conductive via 640 to a device is formed before a second conductive via 658 to a BEOL layer is formed. In some embodiments, different tools may be used (e.g., due to cost), and a conductive via to a BEOL layer may be formed before a conductive via to a device is formed.

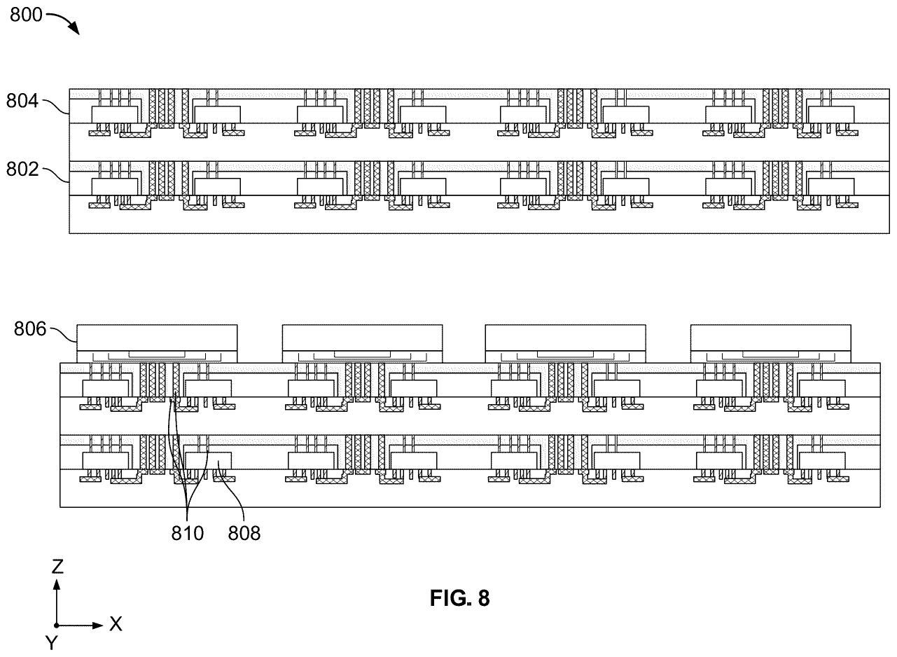

At block 526, the process 500 includes attaching a second substrate 562 to the structure formed at block 522. The second substrate 562 may be disposed on the dielectric layer 546. The dielectric layer 546 may be prepared for bonding, and the second substrate 562 may be directly bonded to the dielectric layer 546. The second substrate 562 may include an upper layer 564 and a lower layer 566. In some embodiments, the upper layer 564 may include one or more devices, a bulk semiconductor material, or other circuitry disposed thereon. In some embodiments, the lower layer 566 may include a second BEOL layer. In some embodiments, the second substrate includes the structure at block 524 (e.g., structure 200, or any suitable structure 250, 260, 270, 280, 301, 401, etc.). At block 528, the process 500 includes removing the support layer 540 and/or the protective layer 538 from the BEOL layer 532. In some embodiments, the second substrate 542 may be used as a handling substrate. In some embodiments, second substrate 542 may be thinned (e.g., for use in multiple stacked substrates or structures, such as embodiments in FIG. 8).

FIG. 6 shows some intermediate structures illustrating an example method or process 600 of forming via and/or backside connections disposed through first and second dielectric layers, in accordance with embodiments of the present disclosure. The process 600 may continue from the block 510 of the process 500 as described regarding FIG. 5. The process 600 includes forming a first dielectric layer over a second side of the semiconductor substrate, the second side opposite to the first side, where the first dielectric layer includes a first dielectric material. In some embodiments, block 602 of FIG. 6 corresponds to (e.g., is similar to, the same as) block 510 of FIG. 5. At block 602, the process 600 includes removing a portion 630 of the substrate through thinning. The substrate may be thinned to have a thickness of 20 μm or less, 16 μm or less, 5 μm or less, or 0.5 μm or less. In some embodiments, the substrate may be thinned to have substantially the same thickness as the devices 530. Here, the substrate may be planarized to form a planarized substrate 632. At block 604, the process 600 includes forming a first dielectric layer 634 on the planarized substrate 632. At block 606, the process 600 includes patterning the first dielectric layer 634 and the planarized substrate 632 to form first openings 636. The first openings 636 extend through respective dielectric portions of the first dielectric layer 634 and respective substrate portions of the planarized substrate 632 to the respective devices 530.

The process 600 further includes forming a first conductive via extending through the first dielectric layer 634 to the device. At block 608, the process 600 includes forming a first conductive layer 638. In some embodiments, the process 600 includes forming an adhesion and/or barrier layer prior to forming the first conductive layer 638. In some embodiments, forming the first conductive layer 638 includes forming a seed layer. Here, the conductive layer 638 includes one or more portions that fill the first openings 636. The first openings 636 are filled with first conductive material to form first conductive vias 640. In some embodiments, the first conductive material my comprise any suitable conductive material, such as those mentioned in the present disclosure. In some embodiments, the first conductive via (e.g., conductive vias 218, 219, conductive vias 262, 263) may comprise any of silicon, polysilicon, silicide, tungsten, cobalt, TaN (e.g., hexagonal-TaN), Ta (e.g., alpha-Ta), TiN, a NiV alloy, ruthenium, conductive oxides, transparent conductive oxide and/or combinations thereof. In some embodiments, some of the vias may comprise of dielectric material adapted and configured to transmit optical signal or communication. For example, one or more of the conductive vias 218, 219, 262, 263 may comprise an optically conductive or nonconductive transparent material. At block 610, the first conductive layer 638 is thinned, removing a portion 642 such that the first conductive vias 640 have a height along the Z-direction that is substantially the same as a total thickness of the first dielectric layer 634 and/or a substrate portion disposed over the devices 530. That is, upper ends of the first conductive vias 640 may be about a same level as an upper side of the first dielectric layer 634, and lower ends of the first conductive vias 640 may about a same level as an upper side of the devices 530. In some embodiments, the portion 642 may be removed through polishing, such as by using CMP.

The process 600 further includes patterning the first dielectric layer and the semiconductor substrate to define a section including the device and a first dielectric portion disposed over the device, the first dielectric portion including the first dielectric material. At block 612, the process 600 includes patterning the dielectric layer 634 and the planarized substrate 632 to define the sections 644. Here, the sections 644 are separated from adjacent sections by one or more spaces. The sections 644 include a device and a first dielectric portion over the device. In some embodiments, the sections 644 may include a substrate portion disposed between the device and the first dielectric portion.

The process 600 further includes forming a second dielectric portion adjacent to the sidewall, wherein the second dielectric portion is disposed on the circuitry on the first side, where the second dielectric portion includes a second dielectric material different than the first dielectric material. At block 614, the process 600 includes forming a second dielectric layer 646 over the sections 644 and filling the spaces between the sections 644. Here, the second dielectric layer 646 includes dielectric portions 648 disposed on the first dielectric portions of the sections 644 and dielectric portions 650 disposed between the sections 644.

At block 616, the process 600 includes thinning an/or planarizing the second dielectric layer 646 to remove a portion 652. The removed portion 652 may include the dielectric portions 648. At block 618, the process 600 includes patterning dielectric portions 650 to form second openings 654 disposed between the sections 644.

The process 600 further includes forming a second conductive via extending through the second dielectric portion to the circuitry on the first side. At block 620, the process 600 includes forming or depositing a second conductive layer 656. The second conductive layer 656 is formed on the second dielectric layer 646 and fills the second openings 654 with second conductive material to form second conductive vias 658. In some embodiments, the process 600 includes forming an adhesion and/or barrier layer prior to forming the second conductive layer 656. In some embodiments, forming the second conductive layer 656 includes forming a seed layer. The second conductive material my comprise any suitable conductive material, such as those mentioned in the present disclosure. In some embodiments, the second via (e.g., conductive vias 222) may comprise tungsten, copper (Cu), cobalt (Co), etc. At block 622, the process 600 includes thinning and/or planarizing the conductive layer 656 and the second dielectric layer 646 to remove a conductive layer portion 660. For example, the second conductive layer 656 may be polished using CMP such that the conductive vias 658 have a height along the Z-direction that is substantially the same as a total thickness of the sections 644. That is, upper ends of the second conductive vias 658 may be about a same level as an upper side of the first dielectric portion of the sections 644, and lower ends of the second conductive vias 658 may about a same level as an upper side of the BEOL layer 532. The sections 644, the first conductive vias 640, and the second conductive vias 658, and the BEOL layer 532 may form a first structure. Upper sides of the sections 644, the first conductive vias 640, and the second conductive vias 658 may define an upper surface for stacking. In some embodiments, a bonding surface 662 is prepared for direct bonding (e.g., for hybrid bonding). That is, upper sides of the sections 644, the first conductive vias 640, and the second conductive vias 658 may be planarized to form the bonding surface 662.

At block 624, the process 600 includes assembling a stacked structure by stacking a second substrate 664 on the upper surface of the first structure. The second substrate 664 includes a BEOL layer 665. In some embodiments, the second substrate 664 is bonded to the bonding surface 662. In some embodiments, the second substrate 664 may have a different lateral width along the X-and/or Y-directions than the first structure. At the block 626, the second substrate 664 is encapsulated using encapsulant portions 666 such that the stacked structure has substantially the same lateral width along the X-and/or Y-directions. At block 628, the process 600 includes removing a support layer 540 and/or the protective layer 538 from the BEOL layer 532. The process 600 may include removing the support layer 540 and selectively removing the protective layer 538. In some embodiments, the second substrate 664 may be used as a handling substrate. In some embodiments, second substrate 664 may be thinned.

Although FIG. 6 shows a portion of a first dielectric layer 634 on sections 644 is formed before a portion of a second dielectric layer 650 between sections 644 is formed, in some embodiments, a portion of a dielectric layer between sections 544 may be formed before a portion of a dielectric layer on sections 544 is formed.

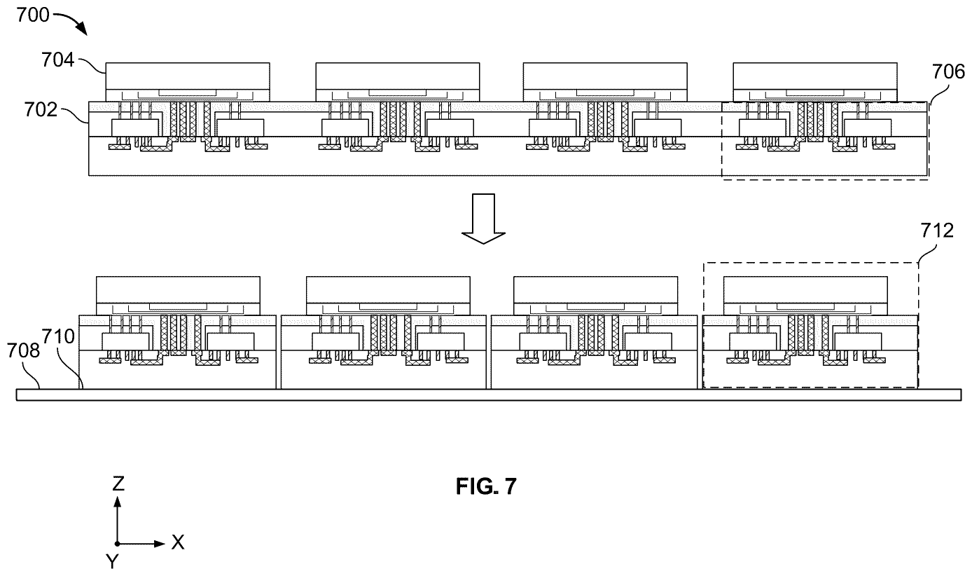

FIGS. 7 and 8 show examples of stacked structures including vias and/or backside connections. In some embodiments, stacked structures may be used in applications with high performance compute modules (e.g., interposers, high bandwidth memory (HBM) stacked directly on graphics processor unit (GPU), stacked heterostructures, and backside power delivery, etc.).

FIG. 7 shows some example structures 700 including via and/or backside connections in a die-to-wafer (D2W) structure, in accordance with embodiments of the present disclosure. In some embodiments, a stacked structure may be assembled by attaching one or more devices, chips, or singulated dies 704 on a substrate or wafer 702 including a plurality of structures 706. In some embodiments, the structure 706 corresponds to structure 200 of FIG. 2A. In some embodiments, any suitable structure such as those mentioned in the present disclosure (e.g., structure 250, 260, 270, 280, 301, 401, etc.) may be used in place of structure 706. In some embodiments, the one or more singulated dies 704 are directly bonded (e.g., hybrid bonded) to the wafer 702, coupling the conductive vias of a respective structure 706 to a respective singulated die 704. Additionally, or alternatively, the one or more singulated dies 704 may be attached to the wafer 702 and/or coupled to the structures 706 through microbumps, solder, and/or other interconnects disposed between the one or more singulated dies 704 and the wafer 702. The wafer 702 may be mounted on a support layer 708 (e.g., a dicing sheet or dicing ring) at an adhesive surface 710 and the wafer may be singulated to define sidewalls of a stacked structure 712, where each stacked structure 712 includes a structure 706 and at least one of the singulated dies 704. In some embodiments, after dicing, a frontside (e.g., BEOL layer) of the stacked structure 712 can by hybrid bonded or flip chip bonded to another substrate.

FIG. 8 shows some example structures 800 including via and/or backside connections in a wafer-to-wafer (W2W) structure and/or a die-to-wafer-to-wafer (D2W2W) structure, in accordance with embodiments of the present disclosure. In some embodiments, a stacked structure may be assembled by attaching a first substrate or wafer 802 to a second substrate or wafer 804. Here, the second wafer 804 is disposed on the first wafer 802. Each of the wafers 802, 804 includes a respective plurality of structures corresponding to the structures 706. In some embodiments, the structure 706 corresponds to structure 200 of FIG. 2A. In some embodiments, any suitable structures such as those mentioned in the present disclosure (e.g., structure 250, 260, 270, 280, 301, 401, etc.) may be used in place the structures of FIG. 8. In some embodiments, the second wafer 804 is directly bonded (e.g., hybrid bonded) to the first wafer 802, coupling the conductive vias of a structure of the first wafer 802 to a structure of the second wafer 804. Additionally, or alternatively, the second wafer 804 may be attached to the first wafer 802, where the respective structures of the wafers 802, 804 are coupled through microbumps, solder, and/or other interconnects disposed therebetween. In some embodiments, assembling the stacked structure further includes attaching one or more devices, chips, or singulated dies 806. The one or more singulated dies 806 may include a backside and a device side. In some embodiments, the device side or backside of one or more of the singulated dies 806 may be attached to a device side or backside of the second wafer 804. Here, a device side of the singulated dies 806 is attached to the second wafer 804 (e.g., a wafer backside of the second wafer 804). In some embodiments, the one or more singulated dies 806 is directly bonded (e.g., hybrid bonded) to the second wafer 804, coupling the one or more singulated dies 806 to respective structures of the second wafer 804. Additionally, or alternatively, the one or more singulated dies 806 may be attached to the second wafer 804, where the one or more singulated dies 806 is coupled to the respective structures of the second wafer 804 through microbumps, solder, and/or other interconnects disposed therebetween. Here, a communication path may be formed between the one or more singulated dies 806 and the devices 808 of the first wafer 802 through the conductive features 810 of the corresponding structures. In some embodiments, the structure may be molded for improved rigidity. In some embodiments, a molding material may be disposed adjacent to or between singulated dies 806.

The embodiments discussed above are intended to be illustrative and not limiting. One skilled in the art would appreciate that individual aspects of the assemblies, device packages, and methods discussed herein may be omitted, modified, combined, and/or rearranged without departing from the scope of the disclosure.

1. A device package comprising:
a semiconductor substrate having a first side, the first side comprising circuitry formed thereon, and a second side opposite the first side, wherein a section of the semiconductor substrate comprises a device;
a first dielectric portion disposed over the section of the semiconductor substrate and the device, wherein the first dielectric portion comprises a first dielectric material;
a second dielectric portion disposed adjacent to a sidewall of the section and over the circuitry on the first side, wherein the second dielectric portion comprises a second dielectric material different from the first dielectric material;
a first conductive via disposed through the first dielectric portion and extending to the device; and
a second conductive via disposed through the second dielectric portion and extending to the circuitry on the first side.

2. The device package of claim 1, wherein the circuitry on the first side is part of a back-end-of-line (BEOL) layer.

3. The device package of claim 2, wherein the semiconductor substrate is bonded to the BEOL layer by direct dielectric bonds formed between a bonding surface of the semiconductor substrate and a bonding surface of the BEOL layer.

4. The device package of claim 2, wherein the semiconductor substrate is bonded to the BEOL layer by direct hybrid bonds formed between a bonding surface of the semiconductor substrate and a bonding surface of the BEOL layer.

5. The device package of claim 2, wherein the second conductive via extends to a first BEOL side of the BEOL layer and is coupled to one or more conductive features extending from the first BEOL side to a second BEOL side of the BEOL layer opposite to the first BEOL side.

6. The device package of claim 1, wherein a third dielectric portion is disposed over the second dielectric portion, and wherein the second conductive via extends through the third dielectric portion to the circuitry on the first side.

7. The device package of claim 6, wherein the third dielectric portion comprises the first dielectric material.

8. The device package of claim 1, wherein the first dielectric portion is disposed vertically adjacent to the device, and wherein the second dielectric portion is disposed laterally adjacent to the device.

9. The device package of claim 1, wherein the device is a first device, the device package further comprising a second device disposed over the semiconductor substrate.

10. The device package of claim 9, wherein the second device is coupled to one or more interconnects of the circuitry on the first side through the second conductive via.

11. The device package of claim 7, wherein the second device is coupled to the first device through the first conductive via.

12. The device package of claim 1, wherein the circuitry on the first side comprises one or more interconnects coupling the device and the second conductive via.

13. The device package of claim 1, wherein the first conductive via comprises a conductive material different from the second conductive via.

14. The device package of claim 1, wherein a width of the first conductive via is smaller than a width of the second conductive via.

15-30. (canceled)

31. A method comprising:
providing a semiconductor substrate having a first side, wherein the first side comprises circuitry formed thereon, and wherein the semiconductor substrate comprises a device;
forming a first dielectric layer over a second side of the semiconductor substrate, the second side opposite to the first side, wherein the first dielectric layer comprises a first dielectric material;
forming a first conductive via extending through the first dielectric layer to the device;
patterning the first dielectric layer and the semiconductor substrate to define a section comprising the device and a first dielectric portion disposed over the device, the first dielectric portion comprising the first dielectric material;
forming a second dielectric portion adjacent to a sidewall of the section, wherein the second dielectric portion is disposed on the circuitry on the first side, and wherein the second dielectric portion comprises a second dielectric material different than the first dielectric material; and
forming a second conductive via extending through the second dielectric portion to the circuitry on the first side.

32. The method of claim 31, wherein the circuitry on the first side is part of a back-end-of-line (BEOL) layer.

33. A device package comprising:
a semiconductor substrate having a first side, the first side comprising circuitry formed thereon, and a second side opposite the first side, wherein a section of the semiconductor substrate comprises a device;
a first dielectric portion disposed over the section and the device, wherein the first dielectric portion comprises a first dielectric material;
a second dielectric portion disposed adjacent to a sidewall of the section and over the circuitry on the first side;
a first conductive via disposed through the first dielectric portion and extending to the device; and
a second conductive via disposed through the second dielectric portion and extending to the circuitry on the first side, wherein a width of the first conductive via is smaller than a width of the second conductive via.

34. The device package of claim 33, wherein the circuitry on the first side is part of a back-end-of-line (BEOL) layer.
